(19) United States
(12) Patent Application Publication
(10) Pub. No.: US 2011/0221509 A1
(43) Pub. Date: Sep. 15, 2011

(54) SENSITIVE PANEL

(75) Inventors: Danilo Antonio Bergamo, Curitiba (BR); Lilian Parol, Curitiba (BR); Marcelo Campani Giesteira, Curitiba (BR)

(73) Assignee: ELECTROLUX DO BRASIL S.A., Curitiba (BR)

(21) Appl. No.: 13/062,757

(22) PCT Filed: Sep. 10, 2009
(86) PCT No.: PCT/BR09/00296

§ 371 Date: May 27, 2011

(30) Foreign Application Priority Data
Sep. 10, 2008 (BR) MU8802068-1

(51) Int. Cl. H03K 17/96

(52) U.S. Cl. 327/517

(57) ABSTRACT

Touch-sensitive or User's finger movement-sensitive panel (1), applied to household appliances such as fridges, washing machines, microwave ovens and stoves, supplied with a touch sensor, capacitive or similar, allowing to control the equipment through the selection of specific functions and characteristics, without the need of gears with mobile pieces to detect the touch or its derivatives for such purpose. The said panel (1) is supplied with a capacitance measurement electronic circuit coupled with a sensitive element (4) conductor of electricity which allows the connection to the panel (1), which is supplied with a conductive element applied on its inner surface. This conductive element (6) allows the extension of the motion perception area next to the external surface or the touch on it.

### FIELD OF THE INVENTION

This invention refers to a touch-sensitive or user's fingers movement-sensitive panel applied to household appliances such as refrigerators, washing machines, microwave ovens and stoves, through a touch sensor, capacitive or similar, allowing to control the equipment through the selection of specific functions and characteristics, without the need of gears with mobile pieces to detect the touch or its derivatives for that purpose. Such panel is supplied with a capacitance measurement circuit coupled to a sensitive element conductor of electricity which allows the connection to the panel, which is supplied with a conductive element applied on its inner surface. This conductive element allows the extension of the motion perception area next to the external surface or the touch on it.

### BACKGROUND OF THE INVENTION

A capacitor is a device that comprises two conductors separated by a dielectric mean or insulating material. By definition, the capacitor's capacitance is the relation between one of the conductor's charge and the potential difference between them. The capacitive sensors are devices that can detect capacitance variations which might be converted in a deviation of the voltage balance in a bridge made with capacitors and resistors, energized from a voltage source. The voltage deviation will be inversely proportional to the displacement between the boards. The capacitance variations can be caused by changes on the boards areas, in the dielectric constant of the material or in the distance between the boards.

These sensors allow a precise measurement of a great number of physical quantities, such as position, displacement, speed, and linear or angular acceleration of an object; the humidity, gas concentration and the level of liquids and solids; the force, torque, pressure, and temperature; but also detect the objects proximity, the presence of water, people, etc.

Applied in household appliance panels, these devices have a huge repercussion pursuant to the possibility to control the household appliance functionalities from the touch perception or movements on the equipment panel. As usual, panels supplied with capacitive sensors use them coupled to a string that works as an antenna, suffering a deformation when assembling the panel, allowing an increase in the sensitive area, verified by the size of the surface comprehended by the spirals of such spring. That is, the set sensibility to perceive the User approach to the area determined by the panel depends directly on the area defined by the spirals of the spring used by the circuit.

Another restriction refers to the arrangement of the household appliance circuit and panel. Once the spring, connected to the electronic circuit, is the one who has the function of an antenna, detecting the User approach, it must be positioned directly under the panel corresponding figure or icon, which represents the function desired by the User. This implies that the circuit is also placed in that position, forcing an arrangement that enables the positioning of the spring according to the panel functions indications. Thus, there are limitations of size, circuit arrangement and panel limitations, caused by the size of the springs that can be allocated under the panel, as well as by the need to allocate the strings under each icon or figure representative of the desired functions on the panel that is the User interface.

The present invention solves such problems using a conductive element under the panel, as a metallic board or a metallic painting, adhered to its inner wall, which is connected to the electronic circuit through a conductive component, as a spring or a filament.

### STATE OF ART ANALYSIS

Document MU 8200405-6U describes an electronic controller for refrigerators characterized by receiving information from temperature information of the fridge and the compressor and controls a series of activations. Such document does not mention, at any time, the characteristic of touch-sensitivity or movements on the panel, therefore differing from the present invention.

Document US 2005/0179673-A1 describes a panel supplied with a capacitive sensor associated with a spring that serves as the sensor antenna, perceiving the User approach. The document provides for the increase of the device sensitivity through the spring deformation, expanding its coverage area under the panel. However, the document does not advance any possibility to expand this area through the association with an additional conductive element, therefore differing from the exhibitions stated in the present invention.

### DESCRIPTION OF FIGURES

FIG. 1 shows a perspective view of the panel (1) disassembled, pointing out the external part (1), with the figures of orientation (2) of the equipment operation, and the inner part (3), where the spring (4) is shown at its usage place.

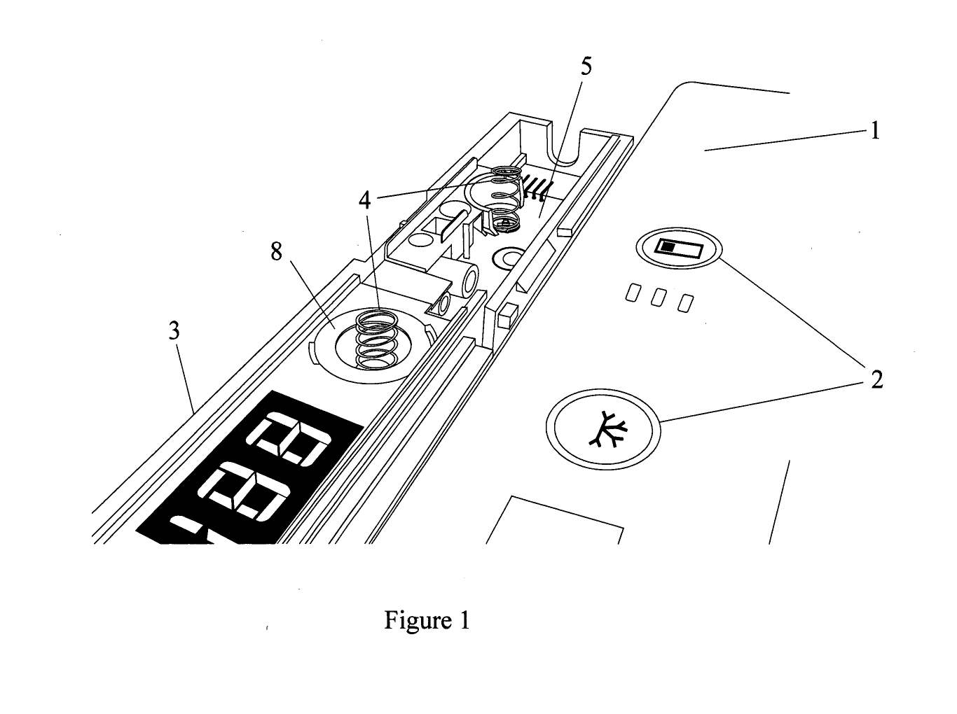

FIG. 2 shows a cut-way perspective of the panel (1) assembled, pointing out the spring position (4) in the operation position, in contact with the conductive element (6) of the inner part (3).

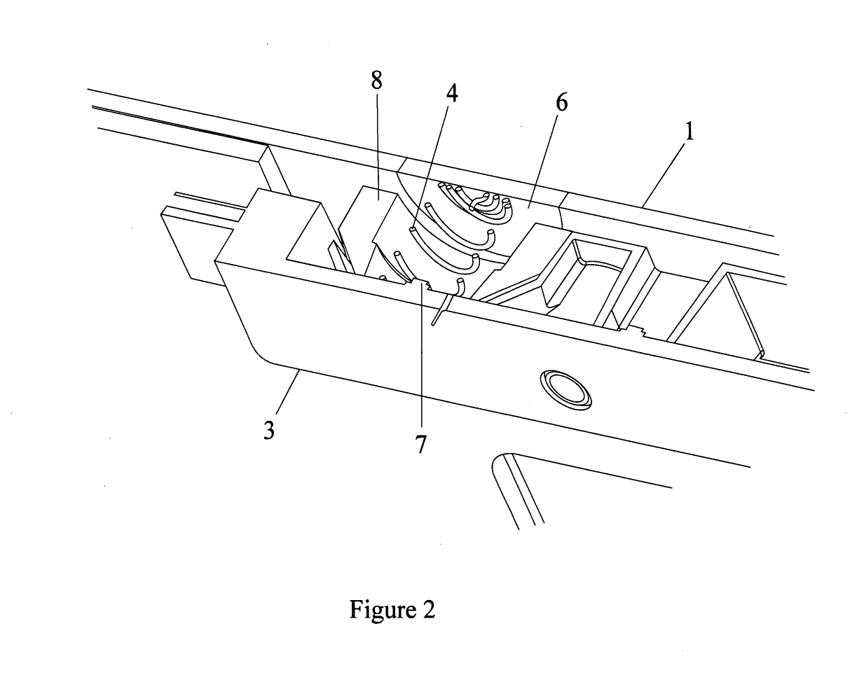

FIG. 3 shows the circuit detail with the spring (4) at its coupling position to the board (5) of the circuit.

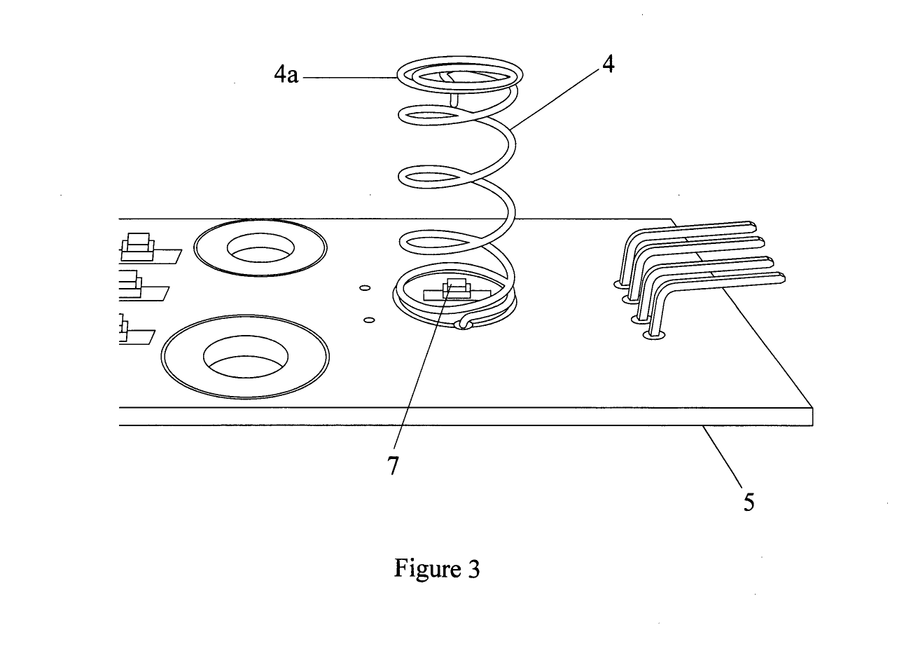

FIG. 4 shows a perspective of the inner view of the panel (1), pointing out the circuit and spring (4) as a whole, when in use, in contact with the conductive element (6).

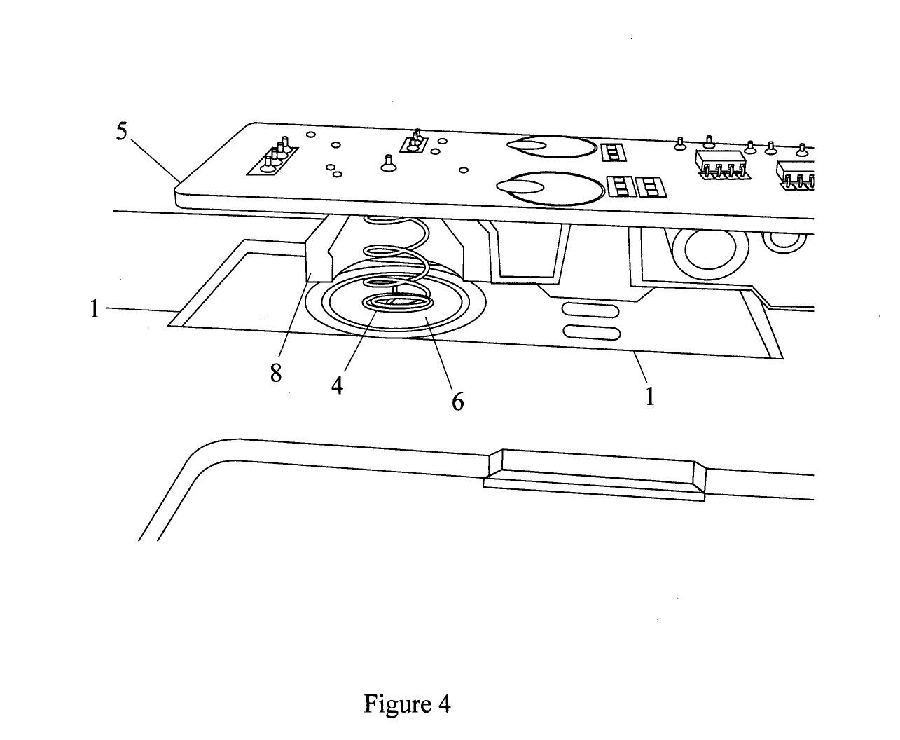

FIG. 5 shows a sidelong cut-way view of the panel (1), pointing out the spring (4) and the circuit (5) in usage position when assembled.

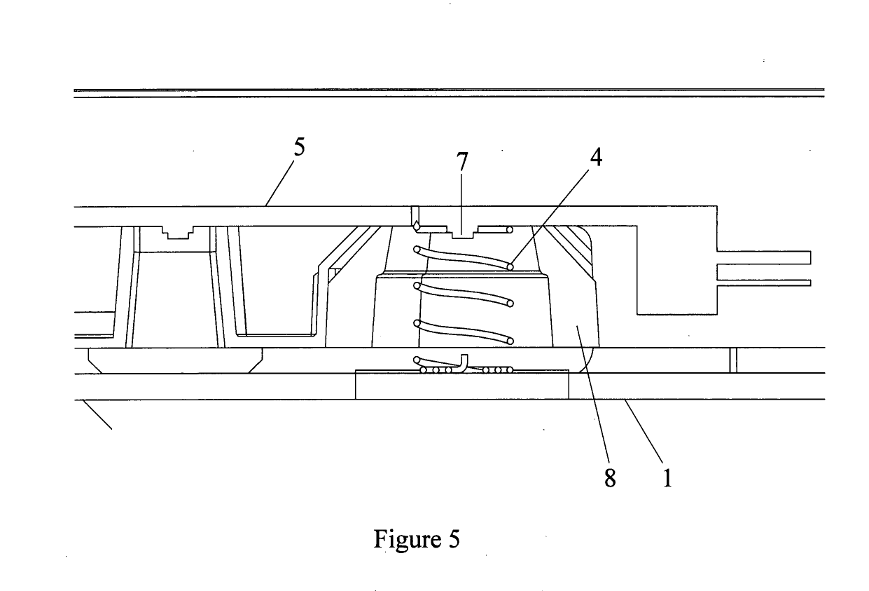

### DETAILED DESCRIPTION OF THE EMBODIMENT

This invention describes a panel (1) used in household appliances that is sensitive to the User's fingers approach on the external surface of the said panel. This can be decorated with representative FIGS. (2) of the household appliance functions. For example, for one arrangement of this invention, the panel (1), applied to a fridge, is supplied with drawings (2) representing the freezing and operation time level functions, in separate areas on the external surface of the panel (1).

For that purpose, the present invention is based on panels for touch and finger movement-sensitive household appliances, with a touch insulating surface, with translucent contrast, preferably the polycarbonate, allowing the lighting by any kind of accessory device that creates and light beam incident on a specific area of the panel or on the whole extension of it. The devices can be several, such as lamps or led.

In order to allow the choice of the household appliance operation mode, the said panel (1) presents the information needed on its surface printed in semi-transparent serigraphic metallic ink, enabling the light passage in order to view the said information.

Thus, certain areas of the panel (1) can be lighted in function of the selection made by the User, revealing the information concerning the equipment operation in the ongoing operation mode or to be defined by the User.

The use of semi-transparent and conductive ink makes the composition of the panel (1) to enable the panel lighting without the need of drilling the piece or its decorative cover, and also allowing the touch or sliding perception on the surface to control the equipment to which the panel (1) is applied.

The movement sensitivity next to the external surface, made by the User, usually, using the fingers, is made through the use of sensors similar to the capacitive sensors, that perceive the variation of the electromagnetic field in the electrode connected to the sensor, causing a capacitance variation between the fingers and the electrode, resulting the reverse variation of the measured voltage value.

The function of the electrode is performed by a tension cylindrical helical spring (4), connected to the sensor perpendicularly to the board plan (5) of the electronic circuit in which the sensor is inserted. Thus, the spring extends to the inner surface of the translucent panel (1), composed by an insulating material. In one arrangement of this invention, the panel (1) is made by a plastic material.

Adhered to the inner surface of the panel (1), on the spot where the spring (4) meets the panel (1), there is a conductive element (6), immediately under the external symbols (2) corresponding to the household appliance functions intended to be controlled. The element (6) is connected to the spring (4) by contact, becoming an extension of it as an electrode, and it can be a metallic piece, such as a disc, or painting with a conductive ink. The final end of the spring (4), which meets the conductive element (6), creates a plain surface (4a) by the concentration of the spirals in a concentric form, able to interact more reliably with the conductive element (6). This, when the spring (4) is pressed upon the panel (1) assembly, it deforms and presses the upper plain surface (4a) against the conductive element (6) under the lower surface of the panel (1), allowing a close contact and increasing the electrode function by the extension of the conductive element (6).

Thus, the spring (4) and the conductive element (6) make up a single set that works as the electrode, and it can assume the needed area, determined by the conductive element (6) format placed under the panel (1). Further, the spring (4) can be connected to the conductive element (6) in any part of it, which implies that the circuit in which the spring (4) is inserted can be complied so as to optimize its geometric arrangement, regardless of where the conductive element (6) is located.

In addition to the aspects already mentioned, the panel (1) is supplied with a lighting system at the corresponding spots to the graphic signals (2) externally allocated that allow the indication of the function operation selected by the User when it is activated. An indicative lamp (7)—LED—assembled on the printed circuit board (5) and located preferably in the middle of the spring (4), has the light directed through a light guide (8), responsible for the lighting of the frontal translucent panel (1).

It is important to state that the User do not touch any energized part of the circuit, interacting only with the external surface of the panel, composed by an insulating material, preferably polycarbonate. In other modalities of the invention: plastic, glass and also acrylic.

This invention is not limited to the representations mentioned or illustrated herein, and it has to be comprehended in its wide scope. Many changes and other representations of the invention will come in mind of those skilled in the technique to which this invention belongs, having the learning benefit presented in previous descriptions and attached drawings. Further, it is to be understood that the invention is not limited to the disclosed specific shape and that changes and other shapes are understood as enclosed within the scope of the attached claims. Although specific terms are nominated herein, they are only used in a generic and descriptive form and not for a limiting purpose.

1. Sensitive panel supplied with a capacitive type electronic movement sensor applied to household appliances, characterized by having a first conductive element (4), connected to the sensor, associated to a second conductive element (6), fastened to the inner surface of the panel (1), making up, as a whole, the sensor electrode.

2. Sensitive panel, according to claim 1, characterized by the first conductive element (4) being a tension cylindrical helical spring (4).

3. Sensitive panel, according to claim 1, characterized by the second conductive element (4) being a metallic piece fastened to the inner surface of the panel (1).

4. Sensitive panel, according to claim 1, characterized by the second conductive element (4) being a painting with a conductive ink on the inner surface of the panel (1).

5. Sensitive panel, according to claim 1, characterized by the panel (1) being translucent.

6. Sensitive panel, according to claim 1, characterized by the panel (1) being supplied with inner lighting in a central position to the spring (4).

7. Sensitive panel, according to claim 1, characterized by the panel (1) being supplied with graphic symbols (2) in order to identify to the household appliance control function.

8. Tension cylindrical helical spring, according to claim 2, characterized by making up an upper plain surface (4a) by the concentration of spirals in concentric form.
